(19) United States
(12) Patent Application Publication
(10) Pub. No.: US 2014/0209856 A1
(43) Pub. Date: Jul. 31, 2014

(54) Light Emitting Device with All-Inorganic Nanostructured Films

(71) Applicant: Sunpower Technologies LLC, (US)

(72) Inventor: Daniel Landry, Redondo Beach, CA (US)

(73) Assignee: Sunpower Technologies LLC, San Marcos, CA (US)

(21) Appl. No.: 13/755,247

(22) Filed: Jan. 31, 2013

(51) Int. Cl. C09K 11/08; H01L 33/06

(52) U.S. Cl. CPC C09K 11/08; H01L 33/06
USPC 257/13; 252/500; 252/521.1; 427/71

(57) ABSTRACT

A fused film and methods for making the fused film to be employed in a light emitting device are provided. In one embodiment, the disclosure provides a method for forming a film from fused all-inorganic colloidal nanostructures, where the all-inorganic colloidal nanostructures may include inorganic semiconductor nanoparticles and functional inorganic ligands that may be fused to form an electrical network that is electroluminescent. In another embodiment, the disclosure provides a light-emitting device including the fused film that minimizes current leakage in the device and provides increased stability, longevity, and luminescent efficiency to the device.

### BACKGROUND

1. Technical Field

The present disclosure relates generally to a light-emitting device, and more specifically to methods and materials for producing an electroluminescent fused film including all-inorganic colloidal nanostructures that may be incorporated into a light-emitting device.

2. Background

Light-emitting devices incorporating thin films of inorganic colloidal semiconductor nanocrystals as electroluminescent layers may be preferred over organic luminescent materials used in organic light emitting diodes (OLEDs) because of benefits such as more pure colors, lower manufacturing cost, lower power consumption, and higher efficiency. Additionally, these inorganic emitters have longer lifetimes versus their organic counterparts.

Prior methods for fabricating thin-film electroluminescent layers from colloidal semiconductor nanoparticles include the use of colloidal nanoparticles with organic, volatile ligands, and/or thin-film post-processing steps that include cleaning excess organic materials and filling film defects with insulating or other materials. These methods have failed to produce all-inorganic, defect-free, nanocrystalline films that achieve required stability, performance or longevity in light-emitting devices.

Semiconductor nanoparticles benefit from quantum confinement effects that occur at the nanometer scale for certain materials allowing the optical and electronic properties of materials to be dependent and tunable based on their size, shape, and composition versus the properties for the same materials at bulk, or greater than nanometer, scale. Furthermore, inorganic colloidal semiconductor nanocrystals can be deposited on both flexible and rigid substrates, over large areas, and via solution-based deposition (i.e., printing) techniques.

The use of semiconductor nanoparticles in light-emitting devices may require that the particles are uniformly arranged and formed into a uniform thin-film upon deposition. Thin-films of colloidal nanocrystals may require electrical communication to exist between the nanoparticles and throughout the film. Furthermore, electroluminescent films from inorganic colloidal nanoparticles may require being substantially free of holes or voids.

Failure to provide electrical communication between the nanoparticles or prevent voids or holes in the nanocrystal thin-films ultimately may prevent charge carriers recombination and the formation of excitons, preventing light emission to occur. Furthermore, current leakage may be caused in the light emitting device, leading to a reduction in the luminescence efficiency and required increase in power consumption of the light-emitting device.

It would be desirable to improve existing methods for producing light-emitting devices with all-inorganic colloidal nanostructures.

### SUMMARY

Embodiments of the present disclosure provide a light-emitting device and methods of making the same. The light-emitting device may include a fused film with an all-inorganic nanostructured layer. In addition, the all-inorganic colloidal nanostructured layer may include semiconductor nanoparticles that may be processed in a solution and formed into inks.

In order to create the ink that may be thermally treated to form the fused film for use in light emitting devices, nanocrystal synthesis may first take place. In nanocrystal synthesis, semiconductor nanoparticles may be fabricated using known techniques via batch or continuous flow wet chemistry processes. Semiconductor nanoparticles used in the present disclosure may be spherical nanometer-scale, crystalline materials, also known as semiconductor nanocrystals or quantum dots. Other shaped nanometer-scale, crystalline particles may be used including oblate and oblique spheroids, rods, wires, other shapes, and combinations thereof. The semiconductor nanoparticles may include metal, semiconductor, oxide, metal-oxides and ferromagnetic compositions. The semiconductor nanoparticles may have a diameter between about 1 nm and about 1000 nm, although typically they are in the 2 nm-10 nm range. Due to the small size of the crystals, quantum confinement effects manifest which results in size, shape, and compositionally dependent optical and electronic properties, versus properties for the same materials in bulk scale.

After the nanocrystal synthesis, the semiconductor nanoparticles may be subject to ligand exchange where organic ligands may be substituted with pre-selected, functional inorganic ligands. The exchange and extraction of organic ligands may provide a solution or ink of all-inorganic colloidal nanostructures that is substantially free of the organic materials. In some embodiments, the ligand exchange may involve precipitating the as-synthesized semiconductor nanoparticles from their original solution, washing, and re-dispersing in a liquid or solvent which either is or includes the ligands to be substituted onto the semiconductor nanoparticles and so completely disassociates the original ligands from the outer surfaces of the semiconductor nanoparticles and links the functional inorganic ligands to the semiconductor nanoparticles.

The functional inorganic ligands may maintain the stability of semiconductor nanoparticles in the solution and provide preferred ordering and close-packing of the semiconductor nanoparticles, without aggregation or agglomeration, via electrostatic forces. Functional inorganic ligands are inter-particle media, including inorganic complexes, ions, and molecules that eliminate insulating organic ligands, stabilize the semiconductor nanoparticles in solution, facilitate close-packing between semiconductor nanoparticles, and create all-inorganic colloidal nanostructures that may be processed in solution to form all-inorganic films.

After formation of the ink including all-inorganic colloidal nanostructures, the ink may be deposited using spin-coating, spray-casting, or inkjet printing techniques on any substrate conducting or insulating, crystalline or amorphous, rigid or flexible. Once deposited on the substrate, the all-inorganic colloidal nanostructured ink may be transformed into a solid, all-inorganic fused film via thermal treatment. The fused film may function as an electroluminescent layer for the finished light-emitting device based on the fused all-inorganic colloidal nanostructures (including inorganic colloidal semiconductor nanoparticles and functional inorganic ligands) incorporated into the fused film. The final material composition, size of the imbedded all-inorganic colloidal nanostructures, and the thickness of the fused film may depend on the light or wavelength region selected for emission and the electronic configuration for the light emitting device.

According to various embodiments of the present disclosure, a light-emitting device may include an anode, a hole transport layer, an all-inorganic colloidal nanostructured layer within the fused film, an electron transport layer, and a cathode. When a voltage is applied to the device, the anode may inject holes into the hole transport layer and the cathode may inject electrons into the electron transport layer, such that the holes meet the electrons, thus defining the regions in or near the boundaries of the all-inorganic colloidal nanostructured layer of the fused film where excitons are recombined to emit light. The injected holes and electrons may migrate toward the oppositely charged electrodes and may be concentrated at semiconductor nanoparticles to form excitons, after which the excitons may recombine to emit light. The wavelength of emitted light may be determined by the composition and size of the semiconductor nanoparticles.

Incorporation of functional inorganic ligands may prevent defects (e.g., voids, holes, cracks) in the fused film within the light-emitting device. Lack of organic materials may remove insulating properties and may increase charge carrier mobility. All-inorganic fused films from all-inorganic colloidal nanostructured inks may improve film density and quality (lacking holes, voids, and insulating materials), thin-film manufacturing yields, and device performance and longevity. The functional inorganic ligands may be implemented in the final materials design of the semiconductor nanostructured film, act to fuse nanostructures in solid films, and provide electronic transport and networking between semiconductor nanoparticles and throughout the fused film, improving charge carrier mobility and increased performance within the light-emitting device.

In one embodiment, a film comprises a network of fused, all-inorganic nanostructures, wherein the nanostructures include a semiconductor nanoparticle fused with a functional inorganic ligand; and wherein electrical communication exists between the nanostructures and throughout the film.

In another embodiment, a light-emitting device comprises an electroluminescent film comprises an electroluminescent film comprising fused all-inorganic nanostructures, wherein the nanostructures include a semiconductor nanoparticle fused with a functional inorganic ligand; and wherein electrical communication exists between the nanostructures and throughout the film; a first electrode; and a second electrode arranged opposite to the first electrode, wherein the electroluminescent film of fused all-inorganic nanostructures is positioned between the first and second electrodes.

In another embodiment, a method of fabricating an all-inorganic colloidal nanostructured layer comprises synthesizing nanocrystals to form semiconductor nanoparticles; dissolving the semiconductor nanoparticles in an immiscible, non-polar solvent to form a non-polar solution; exchanging organic ligands that cap the semiconductor nanoparticles with functional inorganic ligands in a combined solution; extracting the organic ligands from the combined solution; depositing the semiconductor nanoparticles and the functional inorganic ligands on a substrate; and heating the semiconductor nanoparticles and the functional inorganic ligands using a low-temperature thermal treatment to transition the semiconductor nanoparticles and the functional inorganic ligands into a solid and form an all-inorganic fused film.

Additional features and advantages of an embodiment will be set forth in the description which follows, and in part will be apparent from the description. The objectives and other advantages of the invention will be realized and attained by the structure particularly pointed out in the exemplary embodiments in the written description and claims hereof as well as the appended drawings.

It is to be understood that both the foregoing general description and the following detailed description are exemplary and explanatory and are intended to provide further explanation of the invention as claimed.

### BRIEF DESCRIPTION OF THE DRAWINGS

Embodiments are described by way of example with reference to the accompanying figures, which are schematic and are not intended to be drawn to scale. Unless indicated as representing the prior art, the figures represent aspects of the invention.

FIG. 1 is a block diagram of a process for producing a fused film including an all-inorganic colloidal nanostructured ink, according to an embodiment.

FIG. 2 depicts a light-emitting device with an incorporated fused film, according to an embodiment.

### DETAILED DESCRIPTION

Reference will now be made in detail to the preferred embodiments, examples of which are illustrated in the accompanying drawings. The embodiments described above are intended to be exemplary. One skilled in the art recognizes that numerous alternative components and embodiments that may be substituted for the particular examples described herein and still fall within the scope of the invention.

The present disclosure is described in detail with reference to embodiments illustrated in the drawings, which form a part hereof. In the drawings, which are not necessarily to scale or to proportion, similar symbols typically identify similar components, unless context dictates otherwise. Other embodiments may be used and/or other changes may be made without departing from the spirit or scope of the present disclosure. The illustrative embodiments described in the detailed description are not meant to be limiting of the subject matter presented.

### Definitions

As used herein, the following terms have the following definitions:

“Semiconductor nanoparticles” may refer to particles sized between about 1 and about 100 nanometers made of semiconducting materials.

“Fused film” may refer to a layer of all-inorganic colloidal semiconductor nanostructures that may be converted into a solid matrix after a thermal treatment, and which may additionally be electroluminescent.

### DESCRIPTION OF THE DRAWINGS

Disclosed are embodiments of methods for producing an electroluminescent fused film synthesized from all-inorganic semiconductor nanostructures that may be used in a light-emitting device. In order to form the fused films, an ink, including a layer of all-inorganic semiconductor nanostructures, may be deposited on a substrate and thermally treated to be later incorporated as the fused film in devices designed to emit specific or multiple electromagnetic wavelengths based on the design of the all-inorganic semiconductor nanostructures. Fused films are electrically active and may be electrically connected to other device layers.

All-Inorganic Fused Films from All-Inorganic Nanostructured Inks

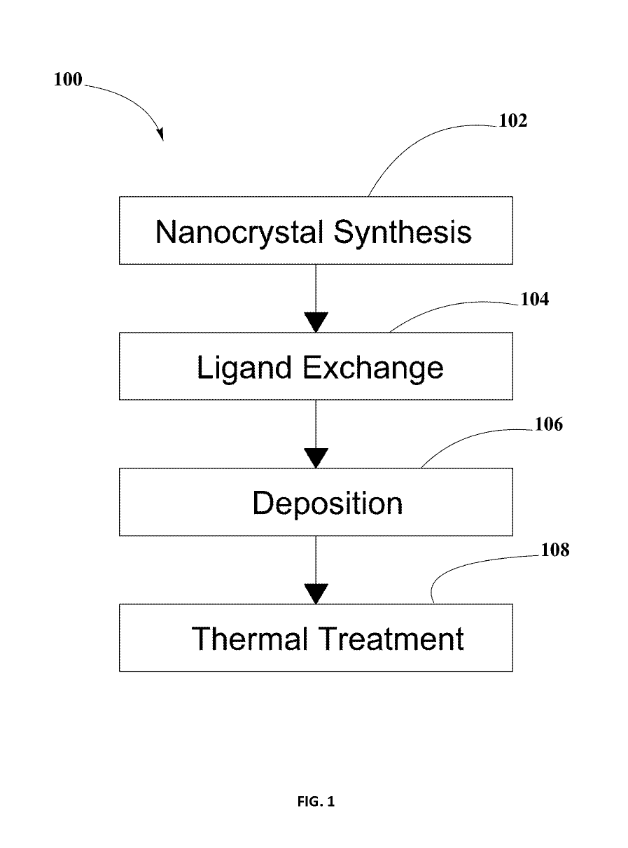

FIG. 1 is a block diagram of a fused film manufacturing method 100.

In order to create the ink that may be thermally treated to form the fused film for use in light emitting devices, nanocrystal synthesis 102 may first take place. In nanocrystal synthesis 102, semiconductor nanoparticles may be fabricated using known techniques via batch or continuous flow wet chemistry processes. The known synthesis techniques for semiconductor nanoparticles may include capping the semiconductor nanoparticle precursors in a stabilizing organic material, or organic ligands, which may prevent the agglomeration of the semiconductor nanoparticle during and after nanocrystal synthesis 102. These organic ligands are long chains radiating from the surface of the semiconductor nanoparticle and may assist in the suspension and/or solubility of the nanoparticle in solvents.

Semiconductor nanoparticles used in the present disclosure may be spherical nanometer-scale, crystalline materials, also known as semiconductor nanocrystals or quantum dots. Other shaped nanometer-scale, crystalline particles may be used including oblate and oblique spheroids, rods, wires, other shapes, and combinations thereof. The semiconductor nanoparticles may include metal, semiconductor, oxide, metal-oxides and ferromagnetic compositions. The semiconductor nanoparticles may have a diameter between about 1 nm and about 1000 nm, although typically they are in the 2 nm-10 nm range. Due to the small size of the semiconductor nanoparticles, quantum confinement effects may manifest, resulting in size, shape, and compositionally dependent optical and electronic properties, versus properties for the same materials in bulk scale.

Semiconductor nanoparticles used in the light-emitting device of the present disclosure can be made of any composition and size that achieves the desired optoelectronic or electroluminescent properties. The composition of these materials may typically include, but not exclusively, compounds formed from elements found in the groups II, III, IV, V, and VI of the periodic table of elements. Binary compounds may include II-VI, III-V, and IV-VI groups and mixtures thereof. Examples of such binary semiconductor materials that nanocrystals are composed of include ZnS, ZnSe, ZnTe, CdS, CdSe, CdTe, HgS, HgSe, HgTe (II-VI materials), PbS, PbSe, PbTe (IV-VI materials), AIN, AIP, AIAs, AISb, GaN, GaP, GaAs, GaSb, InN, InP, InAs, and InSb (III-V materials). In addition to binary semiconductor nanocrystals, the semiconductor nanoparticles of the present disclosure may be unary, ternary, quaternary, and quinary semiconductor nanocrystals and combinations and mixtures of the materials thereof.

In some embodiments of the present disclosure, semiconductor nanoparticles may include core-shell type semiconductors in which the shell is one type of semiconductor and the core is another type of semiconductor. In other embodiments, semiconductor nanoparticles may include metal, oxide, and metal-oxide compounds or core-shell compositions, and mixtures thereof, which are electroluminescent, semi-conductive, or conductive.

Additionally, fused film manufacturing method 100 may involve ligand exchange 104, in which a substitution of organic ligands with functional inorganic ligands may be performed. Generally, functional inorganic ligands may be dissolved in a polar solvent, while organic capped semiconductor nanoparticles may be dissolved in an immiscible, generally non-polar, solvent. These two solutions may then be combined and stirred for about 10 minutes, after which a complete transfer of semiconductor nanoparticles from the non-polar solvent to the polar solvent may be observed. Immiscible solvents may facilitate a rapid and complete exchange of organic ligands with functional inorganic ligands.

Functional inorganic ligands may be soluble functional reagents that are free from organic functionality, may have a greater affinity to link to the semiconductor nanoparticles than the organic ligands, and therefore, may displace the organic ligands from organic capped semiconductor nanoparticles. Ligand exchange 104 may involve precipitating the organic capped semiconductor nanoparticles from their original solution containing organic ligands, washing, and re-dispersing in a liquid or solvent which either is or includes the functional inorganic ligands. These functional inorganic ligands may disassociate the organic ligands from the outer surfaces of the organic capped semiconductor nanoparticles and may link the functional inorganic ligands to the semiconductor nanoparticles. The functional inorganic ligands may maintain the stability of semiconductor nanoparticles in the solution and may provide preferred ordering and close-packing of the semiconductor nanoparticles without aggregation or agglomeration via electrostatic forces. Functional inorganic ligands may assist in the suspension and/or solubility of the semiconductor nanoparticle in solvents or liquids. Once applied, the functional inorganic ligands may not substantially change the optoelectronic characteristics of the semiconductor nanoparticles originally synthesized with organic ligands.

Functional inorganic ligands may include materials that are the same as the coordinated semiconductor nanoparticle or different to design and affect the electronic, optical, magnetic, or other properties for the final fused films. In some embodiments, two or more types of semiconductor nanoparticles may be separately fabricated. Each different type of semiconductor nanoparticle may be subject to the exchange of organic ligands for functional inorganic ligands and the extraction of post-exchanged organic ligands. Subsequently, the two types of semiconductor nanoparticles with functional inorganic ligands may be mixed in a solution to create a heterogeneous mixture. A plurality of semiconductor nanoparticle compositions and/or sizes can be included in the all-inorganic colloidal nanostructured ink. Functional inorganic ligands fused with semiconductor nanoparticles may have the beneficial effect of making nanostructured surfaces more stable to oxidation and photoxidation and increase material performance and longevity.

Functional inorganic ligands may include suitable elements from groups such as polyatomic anions, transition metals, lanthanides, actinides, chalcogenide molecular compounds, Zintl ions, inorganic complexes, metal-free inorganic ligands, and/or a combination including at least one of the foregoing.

In some embodiments, functional inorganic ligands may be partially volatilized, where some portion of the functional inorganic ligand remains as solid state electronic material within the nanostructured ink.

Examples of polar solvents containing functional inorganic ligands may include 1,3-butanediol, acetonitrile, ammonia, benzonitrile, butanol, dimethylacetamide, dimethylamine, dimethylethylenediamine, dimethylformamide, dimethylsulfoxide (DMSO), dioxane, ethanol, ethanolamine, ethylenediamine, ethyleneglycol, formamide (FA), glycerol, methanol, methoxyethanol, methylamine, methylformamide, methylpyrrolidinone, pyridine, tetramethylethylenediamine, triethylamine, trimethylamine, trimethylethylenediamine, water, and mixtures thereof.

Examples of non-polar or organic solvents containing organic ligands may include pentane, pentanes, cyclopentane, hexane, hexanes, cyclohexane, heptane, octane, isooctane, nonane, decane, dodecane, hexadecane, benzene, 2,2,4-trimethylpentane, toluene, petroleum ether, ethyl acetate, diisopropyl ether, diethyl ether, carbon tetrachloride, carbon disulfide, and mixtures thereof; provided that organic solvent is immiscible with polar solvent. Other immiscible solvent systems that are applicable may include aqueous-fluorous, organic-fluorous, and those using ionic liquids.

The exchange and extraction of the organic ligands in ligand exchange 104 may provide a solution or ink of all-inorganic colloidal nanostructures that may be substantially free of organic materials. In some embodiments, the relative concentration of the organic ligands to the semiconductor nanoparticle in the solution of the functional inorganic ligand may be less than about 10%, 5%, 4%, 3%, 2%, 1%, 0.5%, and/or 0.1% of the concentration in a solution of the semiconductor nanoparticle with the organic ligands.

Organic materials in organic ligands are known to be less stable and more susceptible to degradation via oxidation and photo-oxidation; therefore, all-inorganic materials may enhance the stability, performance and longevity of the device. In addition, organic materials may act as insulating agents that prevent the efficient transport of charge carriers between semiconductor nanoparticles, resulting in decreased device efficiencies.

Semiconductor nanoparticles with inorganic functional ligands may differ from core/shell semiconductor nanoparticles where one semiconductor nanoparticle has an outer crystalline layer with a different chemical formula. The crystalline layer, or shell, generally forms over the entire semiconductor nanoparticle but, as used in the present disclosure, core/shell semiconductor nanoparticles may refer to those semiconductor nanoparticles where at least one surface of the semiconductor nanoparticle is coated with a crystalline layer. While the functional inorganic ligands may form ordered arrays that may radiate from the surface of a semiconductor nanoparticle, these arrays may differ from a core/shell crystalline layer, as they are not permanently bound to the core semiconductor nanoparticle in the all-inorganic colloidal nanostructured ink.

After ligand exchange 104, which may form an all-inorganic colloidal nanostructured ink, the ink may undergo a deposition 106 over a substrate or may be deposited as additional layers to all-inorganic fused films. Deposition 106 may include suitable techniques such as blading, growing three-dimensional ordered arrays, spin coating, spray coating, spray pyrolysis, dipping/dip-coating, sputtering, printing, inkjet printing, and stamping, among others.

Following deposition 106, the all-inorganic colloidal nanostructured ink may be transformed into a solid, all-inorganic fused film via thermal treatment 108. Crystalline films from the all-inorganic colloidal nanostructures may be formed by a low temperature thermal treatment 108. In at least one embodiment, thermal treatment 108 of the colloidal material may include heating to temperatures between about less than about 350, 300, 250, 200, 150, 100 and/or 80° C. The fused film may maintain approximately the same optoelectronic characteristics as the all-inorganic colloidal nanostructured ink or solution including the all-inorganic colloidal nanostructures. This may require that the fused film substantially maintains the same size and shape of the semiconductor nanoparticles that were deposited from the all-inorganic colloidal nanostructured ink. Excessive thermal treatment 108 may create fused films that do not maintain colloidal nanostructures and may result in fused films that have optoelectronic characteristics more closely performing to the respective bulk semiconductor material. Deposition 106 of all-inorganic colloidal nanostructured inks and film fusing via thermal treatment 108 to create all-inorganic colloidal nanostructured films may be performed in repetition to achieve desired film characteristics, including multiple layers, for use in the light-emitting device.

Light-Emitting Devices with Electroluminescent Films Including All-Inorganic Colloidal Nanostructures

The fused film may function as an electroluminescent layer for the finished light-emitting device. The final material composition, size of the imbedded all-inorganic colloidal nanostructures, and the thickness of the fused film may depend on the light or wavelength region selected for emission and the electronic configuration for the light emitting device.

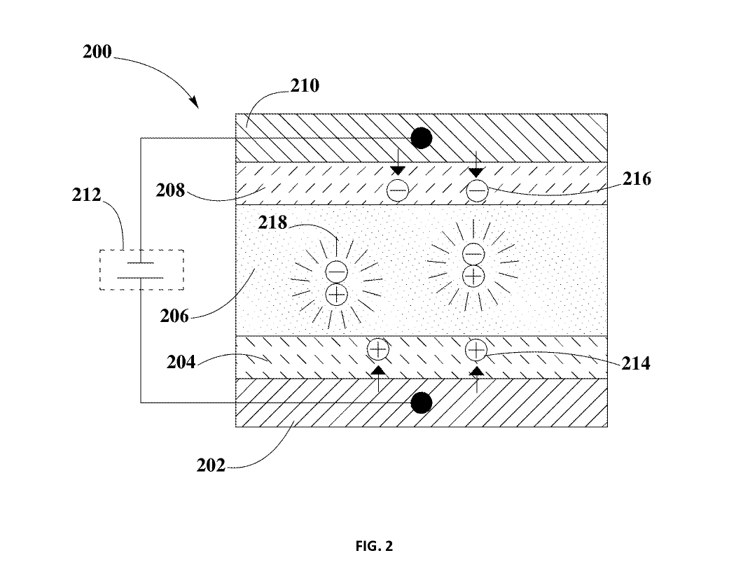

FIG. 2 shows a light-emitting device 200 that may include a cathode 202, a hole transporting layer 204, a fused film 206 including an all-inorganic colloidal nanostructured layer, an electron transporting layer 208, and an anode 210. Light-emitting device 200 may as well be connected to a voltage source 212. When voltage source 212 applies a voltage to cathode 202 and anode 210, cathode 202 may inject holes 214 into hole transporting layer 204, and anode 210 may inject electrons 216 into electron transporting layer 208, such that holes 214 meet electrons 216 in the region of all-inorganic colloidal nanostructured layer within fused film 206, thus defining the regions of recombination for light 218 emission. Injected holes 214 and electrons 216 may migrate toward the oppositely charged electrodes and may be concentrated at a semiconductor nanoparticle within fused film 206 to form excitons, after which the excitons may recombine to emit light 218. The wavelength of emitted light 218 may be determined by the composition and size of the semiconductor nanoparticles.

According to the present disclosure, all-inorganic colloidal nanostructured layer of fused film 206 within light-emitting device 200 may be electroluminescent and may emit light 218 in specific or multiple electromagnetic wavelengths. Examples of specific emitted light 218 may include visible (e.g,. blue, red, green), ultraviolet, and/or infrared regions of the electromagnetic spectrum. Examples of multiple or mixed wavelengths includes white light that in turn may include blue, red, and green visible light regions simultaneously. A plurality of semiconductor nanoparticles, including different composition of materials and/or sizes, each emitting a different wavelength, may facilitate white light or other mixed spectrum emission. In addition, light 218 emitted from fused film 206 may be mixed with light 218 emitted from a region other than fused film 206 to obtain white light emission.

Light-emitting device 200 and fused film 206 may be combined with a color filter to manufacture display devices. In addition, light-emitting device 200 of the present disclosure can be used to manufacture backlight units and illumination sources for a variety of devices. Fused film 206 may have a monolayer structure where the semiconductor nanoparticles may be arranged in a single layer. Fused films 206 may include a multilayer approach including of a plurality of monolayers, such as a plurality of the above-described monolayer structure where the semiconductor nanoparticles may be arranged in a single layer within each monolayer.

Emitted light 218 from exciton recombination in light-emitting device 200 may take place in the all-inorganic colloidal nanostructured layer in fused film 206, or in the interface between fused film 206 and hole transporting layer 204, and/or the interface between fused film 206 and electron transporting layer 208.

In one embodiment of the present disclosure, hole transporting layer 204 and electron transporting layer 208 may include inorganic materials. In another embodiment, both hole transporting layer 204 and electron transporting layer 208 may include organic materials.

Functional inorganic ligands within fused film 206 may effectively bridge the semiconductor nanoparticles to form an electrical network and facilitate efficient electronic transport between the semiconductor nanoparticles and throughout fused film 206. The fused all-inorganic colloidal nanostructures, and the juncture between them, may generally not have defect states, thus current may flow readily between them. This aspect of fusing all-inorganic colloidal nanostructures, including functional inorganic ligands, may increase the electronic transport properties between nanostructures and throughout fused film 206.

In addition, because the all-inorganic colloidal nanostructured layer within fused film 206 may be substantially free of defects, the interfaces of the this layer may be electronically enhanced, including adjacent layers such as electron transporting layer 208 and hole transporting layer 204. The improvement of such interfaces may facilitate high luminescent efficiency/performance and stability of the light-emitting device 200.

The embodiments described above are intended to be exemplary. One skilled in the art recognizes that numerous alternative components and embodiments that may be substituted for the particular examples described herein and still fall within the scope of the invention.

1. A film comprising a network of fused, all-inorganic nanostructures, wherein the nanostructures include a semiconductor nanoparticle fused with a functional inorganic ligand; and wherein electrical communication exists between the nanostructures and throughout the film.

2. The film of claim 1, wherein the network of fused nanoparticles is electroluminescent.

3. The film of claim 1, wherein the film is substantially inorganic.

4. The film of claim 1, wherein the semiconductor nanoparticles and functional inorganic ligands are colloidal and included in an ink or solution that is deposited on a substrate and fused.

5. The film of claim 1, wherein the wavelength of emitted light by the film is determined by the composition and size of the semiconductor nanoparticles.

6. The film of claim 1, wherein the semiconductor nanoparticles maintain the same size, shape, and opto-electronic properties of the semiconductor nanoparticles that were deposited from an all-inorganic nanostructured ink.

7. The film of claim 1, wherein the film is substantially free of defects.

8. The film of claim 1, wherein the network of fused nanostructures defines a conductive electrical network.

9. The film of claim 1, wherein the semiconductor nanoparticles include materials selected from Group II-VI compounds, Group III-V compounds, Group IV-VI compounds, Group IV compounds, or a mixture thereof.

10. The film of claim 1, wherein the functional inorganic ligands include materials consisting of polyatomic anions, transition metals, lanthanides, actinides, chalcogenide molecular compounds, Zintl ions, inorganic complexes, metal-free inorganic ligands, or a combination thereof.

11. The film of claim 1, wherein the film has a monolayer structure in which the semiconductor nanoparticles are arranged in a single layer.

12. The film of claim 1, wherein the film has a multilayer structure comprising a plurality of monolayers, each monolayer having a plurality of the semiconductor nanoparticles arranged in a single layer.

13. The film of claim 1, wherein the semiconductor nanoparticles are quantum dots.

14. A light-emitting device, comprising:
an electroluminescent film comprising fused all-inorganic nanostructures, wherein the nanostructures include a semiconductor nanoparticle fused with a functional inorganic ligand; and wherein electrical communication exists between the nanostructures and throughout the film;
a first electrode; and
a second electrode arranged opposite to the first electrode,
wherein the electroluminescent film of fused all-inorganic nanostructures is positioned between the first and second electrodes.

15. The light-emitting device of claim 14 wherein the first electrode is a hole injecting electrode and the second electrode is an electron injecting electrode.

16. The light-emitting device of claim 14, further comprising a hole transport layer in contact with the first electrode and an electron transport layer in contact with the second electrode.

17. The light-emitting device of claim 14, wherein the electroluminescent layer has a monolayer structure in which the semiconductor nanoparticles are arranged in a single layer.

18. The light-emitting device of claim 14, wherein the electroluminescent layer has a multilayer structure comprising a plurality of monolayers, each monolayer having a plurality of the semiconductor nanoparticles arranged in a single layer.

19. The light-emitting device of claim 14, wherein the semiconductor nanoparticles are quantum dots.

20-25. (canceled)
